(19) United States
(12) Patent Application Publication
(10) Pub. No.: US 2009/0050272 A1
(43) Pub. Date: Feb. 26, 2009

(54) DEPOSITION RING AND COVER RING TO EXTEND PROCESS COMPONENTS LIFE AND PERFORMANCE FOR PROCESS CHAMBERS

(75) Inventors: REED WARREN ROSENBERG, Phoenix, AZ (US); David P. Laube, Mesa, AZ (US); John Monroe Daniel, Chandler, AZ (US); John Gilbert Deem, Chandler, AZ (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(73) Assignee: APPLIED MATERIALS, INC.

(21) Appl. No.: 12/194,750

(22) Filed: Aug. 20, 2008

Related U.S. Application Data
(60) Provisional application No. 60/966,107, filed on Aug. 24, 2007.

(51) Int. Cl. H01L 21/683; C23C 16/00

(52) U.S. Cl. 156/345.51; 118/728

(57) ABSTRACT

A deposing ring and cover ring for extending process components life and performance for process chambers are disclosed. A deposition ring including a protruding surface is positioned in spaced apart relation with a cover ring including a depressed surface. Indicated surfaces of the deposition ring and cover ring may be covered with a coating to improve adhesion of deposited materials.

### RELATED APPLICATIONS

The present application is related to, incorporates by reference and hereby claims the priority benefit of U.S. Provisional Patent Application No. 60/966,107, filed Aug. 24, 2007 and assigned to the assignee of the present application.

### BACKGROUND

1. Field

Embodiments of the present invention relate to the field of semiconductor processing and manufacturing. More particularly embodiments of this invention relate to deposition rings and cover rings.

2. Background Information

The fabrication of semiconductor devices requires extensive chemical processing of the surface and body of a substrate. Such processing typically involves chemical reactions such as, for example, diffusion, oxidation and deposition. In deposition applications, species from a source such as a target, a gas inlet manifold and the like may deposit on exposed internal chamber surfaces, including the chamber wall, substrate pedestal assemblies, electrostatic chucks and other hardware. Physical vapor deposition (PVD) is one process which can be used to make such a deposit.

A process kit is typically used in the deposition process to protect the electrostatic chuck from exposure to the deposition species, and to intercept such stray species. A process kit may include a deposition ring and/or cover ring. The deposition ring rests upon a circumferential flange extending from an outer edge of the electrostatic chuck. The support surface of the electrostatic chuck, upon which a substrate is retained, has a diameter that is slightly smaller than the diameter of the substrate. As a result, the substrate retained by the electrostatic chuck overhangs an inner portion of the top surface of the deposition ring.

While a process kit is useful for shielding the electrostatic chuck during the deposition process, deposition rings and cover rings oftentimes cannot meet full process target life before process failure due to particle deposits and arcing. These particle deposits and arcing are directly related to specific parts and in particular with the characteristics of the deposition ring and cover ring. In accordance with embodiments of the present invention, it has been determined from analyses of the failure mechanisms that an improvement in full life with enhanced particle performance has been obtained.

### SUMMARY

Embodiments of the present invention disclose a deposition ring and cover ring for extending process components life and performance for process chambers. In an embodiment, the deposition ring includes an inside lip which forms an obtuse angle with the flat inner edge surface. In an embodiment, the deposition ring includes a protruding surface which is positioned in spaced apart relation with a depressed portion of a cover ring. In an embodiment, indicated surfaces of the deposition ring and cover ring are covered with a coating to improve adhesion of deposited materials. The deposition ring may be configured relative to the cover ring so that a molecule cannot reach the area where the cover ring is seated on the deposition ring in three or less bounces.

### BRIEF DESCRIPTION OF THE DRAWINGS

FIG. 1 is a top view illustration of a deposition ring.

FIG. 2 is a sectional view illustration of the deposition ring in FIG. 1 taken along section X-X.

FIG. 3 is a top view illustration of a cover ring.

FIG. 4 is a sectional view illustration of the cover ring in FIG. 3 taken along section A-A.

FIG. 5A is a sectional view illustration of a deposition ring and cover ring.

FIG. 5B is a sectional view illustration of a deposition ring and cover ring.

FIG. 6 is an illustration for a method of forming a coating on an indicated surface of a deposition ring or cover ring.

### DETAILED DESCRIPTION

Embodiments of the present invention disclose a deposition ring and cover ring for extending process components life and performance for process chambers.

Various embodiments described herein are described with reference to figures. However, certain embodiments may be practiced without one or more of these specific details, or in combination with other known methods and configurations. In the following description, numerous specific details are set forth, such as specific configurations, compositions, and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment” or “an embodiment” means that a particular feature, configuration, composition, or characteristic described in connection with the embodiment is included in at least one embodiment of the invention. Thus, the appearances of the phrase “in one embodiment” or “an embodiment” in various places throughout this specification are not necessarily referring to the same embodiment of the invention. Furthermore, the particular features, configurations, compositions, or characteristics may be combined in any suitable manner in one or more embodiments.

In one aspect, embodiments of the invention eliminate and/or minimize low energy, low angle back-scatter deposition underneath a substrate positioned over a deposition ring in order to eliminate and/or minimize the potential for arcing. It has been determined in accordance with embodiments of the invention to change the area for deposited material (ex. deposition species deposits) from that of high residual stress to one of consistent stress, and to lower the amount of deposited material in this area.

In another aspect, by changing the back-scatter deposition path from the inner part of the deposition ring to the rear part of the deposition ring where it meets the cover ring, arcing is eliminated and/or minimized in this area. The combination of the improved deposition ring with cover ring functions to eliminate and/or minimize any deposited material from reaching the deposition ring where it comes into contact with the cover ring.

In yet another aspect, the deposition ring and cover ring are selectively covered with a coating to improve adhesion of deposited materials during process chamber operation. In an embodiment the coating is a composite twin wire arc spray (TWAS) coating comprising a bond coating and a top coating. The bond coating greatly increases the adhesion of the composite TWAS coating to the deposition ring and cover ring. The top coat increases the adhesion of deposited material to the composite TWAS coating. By combining the aforementioned mechanical improvements along with a coating on the parts, the parts are able to reach full process target life.

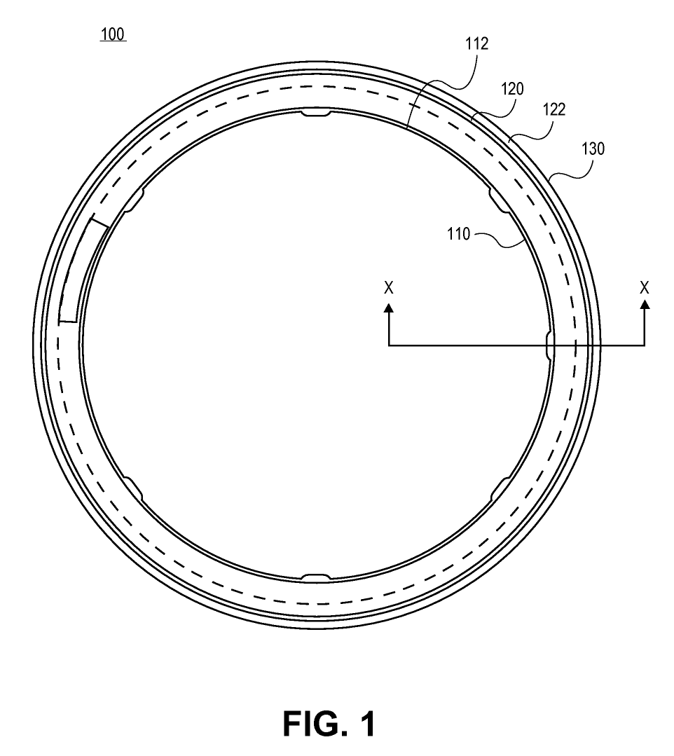

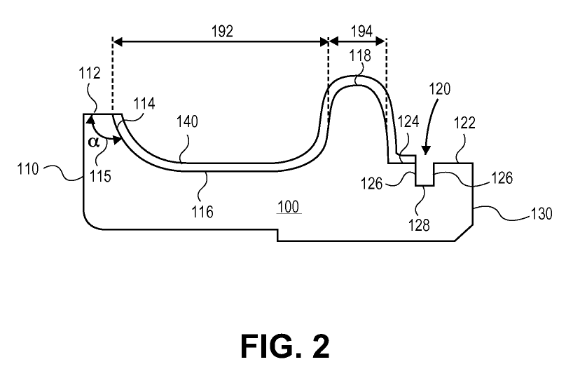

FIG. 1-FIG. 2 are illustrations of an embodiment in which a deposition ring 100 is configured to contact and shield an electrostatic chuck (not shown) upon which a substrate such as a silicon wafer or photomask sits during a deposition process, such as during a PVD deposition process. Embodiments of the invention can be used in PVD based processes for most if not all of the various sputter source technologies. This includes at least PVD, IMP, SIP, eSIP and variations on each of those methods of PVD deposition. Processes include all metal sputter processes in their pure, mixed metal, oxide, nitride or silicide deposited films. While the deposition ring 100 shown in FIG. 1 is annular, it is to be appreciated that other configurations such as square are possible.

Deposition ring 100 may be fabricated from a suitable ceramic such as, but not limited to, aluminum oxide. In an embodiment, coating 140 covers portions of the deposition ring which are exposed to the deposition species. In an embodiment, coating 140 covers inside lip 114, collection cavity surface 116, protruding surface 118 and optionally a portion of surface 124. Coating 140 may, for example, include a surface roughness Ra which improves the adhesion of deposition species deposits.

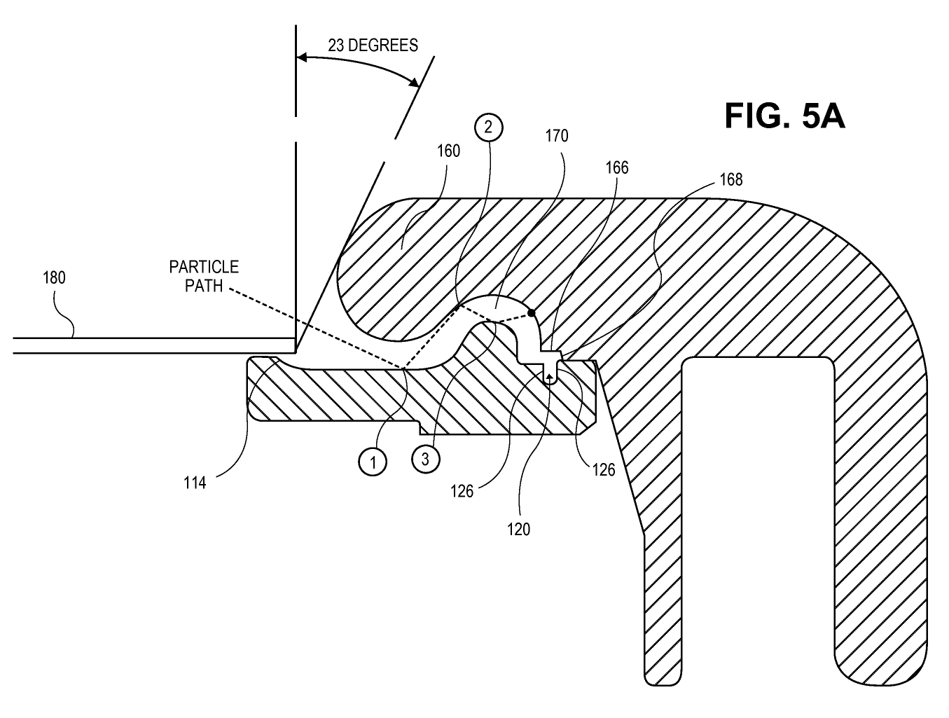

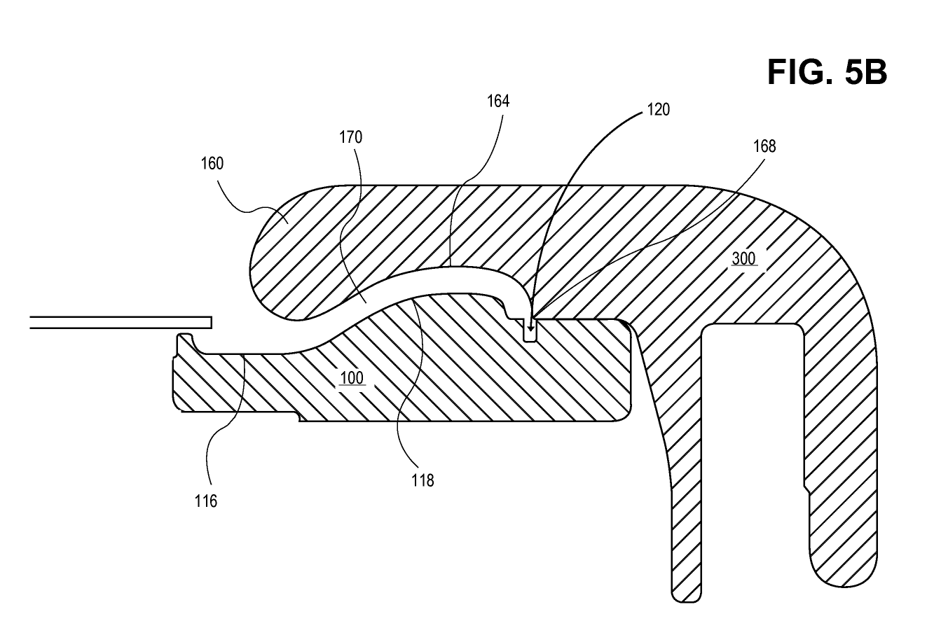

In an embodiment, deposition ring 100 includes an inner wall 110 and an outer wall 130. As shown in FIG. 2, a flat inner edge surface 112 is positioned proximate the inner wall 110. An inside lip 114 is immediately adjacent the flat inner edge surface 112. In an embodiment, inside lip 114 forms an obtuse angle 115 with the flat inner edge surface 112. The obtuse angle 115 is a particular improvement which increases the manufacturability of the deposition ring 100. Conventional deposition rings include a right angle where a vertical inside lip is immediately adjacent a flat inner edge surface. As a result, conventional ceramic deposition rings are prone to chipping during texturing of the inside lip by, for example, grit blasting. The obtuse angle 115 according to an embodiment is less prone to chipping, which allows for the deposition of a more uniform coating 140 on the inside lip 114. Additionally, the obtuse angle 115 prevents deposition species from depositing onto the backside of the substrate being processed that otherwise would be deposited if inside lip 114 were a vertical wall. Consequently, the potential against arcing between the inside lip 114 and substrate 180 (shown, for example, in FIG. 5A) is improved.

Referring again to FIG. 2, in an embodiment, inside lip 114 is a portion of a collection cavity surface 116 extending from the flat inner edge surface 112. As shown in FIG. 2, collection cavity surface 116 may be recessed into deposition ring 100 and extend from the flat inner edge surface 112 to a protruding surface 118. In an embodiment shown in FIG. 2, portions of the collection cavity surface 116 which extend from the flat inner edge surface 112 and protruding surface 118 are curved inward, or concave, while a middle portion is substantially flat. Accordingly, the collection cavity surface 116 may include a substantially flat portion between inwardly curved, or concave, portions. In another embodiment, the entirety of the collection cavity surface 116 is curved inward, or concave.

A particular advantage, is that an intrinsically compressive deposit such as a Ta/TaN deposit can be formed on the curved inward, or concave, collection cavity surface 116 (or coating layer 140) with improved adhesion. Conventional collection surfaces have a curved convex portion upon which deposition species accumulate to form deposits. However, where compressive deposits, which can have a stress of at least 4000-6000 psi, are formed thereon the deposits have a tendency to flake or pop off the collection surface because the curved convex portions induce a tensile strain on the compressive deposits. Embodiments of the invention employing a concave portion of collection cavity surface 116 solve this problem by putting the deposits under compression. As a result, the compressive deposits adhere to the collection cavity surface 116 (or coating layer 140) and do not flake off.

In an embodiment, the collection cavity surface 116 spans a greater horizontal distance 152 than the protruding surface 118 spans a horizontal distance 154. One advantage of this particular configuration is that cover lip 160 is capable of absorbing more deposits than possible with conventional configurations because the cover lip 160 extends over collection cavity surface 116. A greater amount of deposition species deposits are formed on the cover lip 160 than with conventional configurations, and as a result the amount of deposits formed on the collection cavity surface 116 is reduced.

Referring again to FIG. 2, the deposition ring 100 may further contain additional features proximate the outer wall 130 which aid in preventing deposited material from reaching the deposition ring where it comes into contact with the cover ring. In an embodiment, deposition ring 100 includes an isolation notch 120 including a lower surface 128 and sidewalls 126. In an embodiment, isolation notch 120 has a rectangular cross-section, although other configurations are possible. Isolation notch 120 is surrounded by a surface 124 and land 122 to support a cover ring. In an embodiment, surface 124 and land 122 are planar surfaces. In an embodiment, flat inner edge 112 and land 122 are both smooth planar surfaces which are not covered with coating 140. In such an embodiment, flat inner edge 112 is not covered with coating 140 so as to be able to provide a uniform and small distance from the wafer, and land 122 is not covered with coating 140 so as to provide a smooth surface so that a cover ring can slide along the land 122 as the deposition ring and cover ring come into contact with each other.

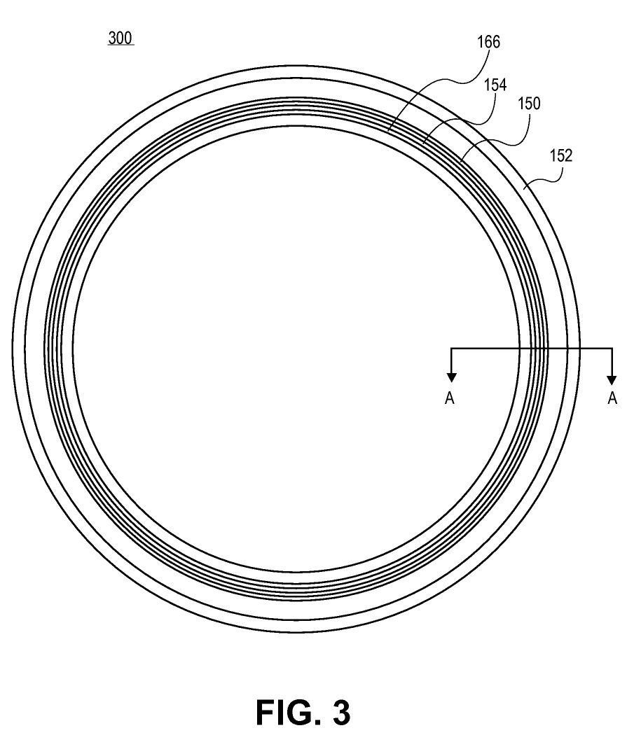

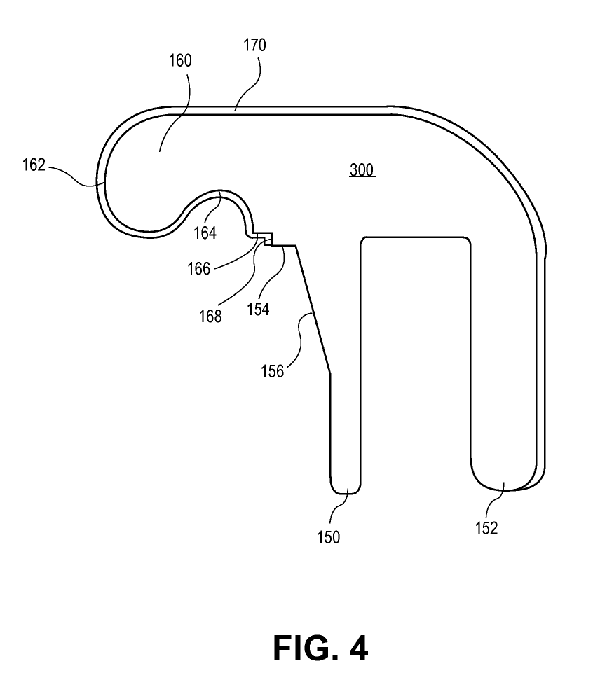

FIG. 3-FIG. 4 are illustrations of an embodiment of a cover ring 300. Cover ring 300 is described as having an annular shape to match an annular deposition ring according to embodiments of the invention described herein. However, cove ring 300 may have a different shape matching that of the deposition ring. The cover ring 300 may be fabricated from a suitable metal such as, but not limited to, titanium and stainless steel, or alternatively a suitable ceramic such as, but not limited to, aluminum oxide.

As shown in FIG. 4, in an embodiment, cover ring 300 includes an inward ring 150 and outward ring 152. The rings 150, 152 extend downward in a spaced apart relation to define a slot to allow engagement with the end of a deposition shield of a processing chamber (not shown). Cover ring 300 further includes a seat 154 and tapered portion 156. The tapered section 156 allows the cover ring 300 and deposition ring 100 to self-align as the rings come into contact with each other. In an embodiment, seat 154 is a smooth, planar surface to allow the seat 154 to slide along the land 122 of deposition ring 100 with minimal particle generation during self-alignment of the rings.

In an embodiment, cover ring 300 includes a lip 160 extending radially inward. Lip 160 may include inside surface 162, which may be rounded. Depressed surface 164 is adjacent the inside surface 162. In an embodiment, depressed surface 164 has the opposite shape as the protruding surface 118.

In an embodiment, coating 170 covers portions of the cover ring 300 which are exposed to the deposition species. In an embodiment, coating 170 covers wall 168, roof 166, depressed portion 164, lip 160, as well as the top and outer portions of the cover ring 300. In an embodiment, coating 170 is not formed on the seat surface 154 and tapered portion 156 so that the smooth seat surface 154 is able to make a uniform connection with land 122.

In an embodiment, coatings 140 and/or 170 are formed on indicated surfaces of the deposition ring 100 and cover ring 300, respectively, in order to provide surfaces for deposited particles and films during a PVD type deposition process. In an embodiment, the indicated surfaces of deposition ring 100 and cover ring 300 are roughened prior to deposition of coatings 140 and 170 by a technique such as bead blasting, for example. In an embodiment, the indicated surfaces have a surface roughness of 90-150 micro-inches.

Coatings 140 and/or 170 may be formed of any material which prevents dislodgement of particles of the roughened surfaces of deposition ring 100 and cover ring 300. In an embodiment, coatings 140 and 170 are metallic coatings. In an embodiment, coatings 140 and 170 can be a metal such as, but not limited to, aluminum, titanium, molybdenum, nickel, or combinations thereof. Coatings 140 and 170 preferably possess a surface roughness Ra which provides an increased surface area, compared to uncoated surfaces of the chamber components, for the purpose of increasing the volume of attachment sites for entrapping and retaining particles and films of the deposition species in the chamber. In an embodiment, coatings 140 or 170 may have a surface roughness Ra of 600-900 micro-inches.

In an embodiment, coatings 140 or 170 can comprise multiple layers. For example, the coatings can be dual layer coatings comprising a first bond coat and a top coat. The bond coat is applied to the pre-roughened surface of the deposition ring or cover ring, and possesses a lower surface roughness Ra than the top coat. While the bond coat may not possess a surface roughness optimized for collecting deposition species, this coating is more continuous and uniform than the top coating and leads to very good adhesion to the pre-roughened surface of the substrate. In an embodiment, the bond coat may have a thickness of 0.002-0.004 inches and a surface roughness of less than 600 micro-inches, and the top coat has a thickness of 0.008-0.013 inches and a surface roughness of 600-900 micro-inches.

As shown in FIG. 5A and FIG. 5B, in an embodiment, the depressed surface 164 and protruding surface 118 are described as having a female-male relation. In such an embodiment, protruding surface 118 is positioned in spaced apart relation with depressed surface 164. For example, protruding surface 118 may fit within depressed surface 164 so that the surfaces are separated by a uniform gap distance between approximately 0.030 inches and 0.090 inches. As shown in FIG. 5A, in an embodiment, protruding surface 118 is described as having a first radius, and depressed surface 164 is described as having a second radius larger than the first radius. Radii vary according to part size. For example, where the substrate is a 200 mm wafer, the radius of protruding surface 118 can be approximately 0.060 inches, and the matching cover ring depressed surface 164 has a radius of approximately 0.109 inches. For example, where the substrate is a 300 mm wafer, the radius of protruding surface 118 can be approximately 0.430 inches, and the matching cover ring depressed surface 164 has a radius of approximately 0.500 inches. Though as shown in FIG. 5B, the surfaces 118, 164 are not necessarily radial. Surfaces 118, 164 may also form other shapes such as v-shaped with the point of the v-shape being rounded.

Referring again to FIG. 5A, in a particular embodiment the cover ring lip 160 is positioned approximately 23 degrees to normal of an outermost edge of a substrate 180. It has been discovered, that in this particular embodiment a greater amount of deposition species deposits are formed on the cover lip 160 than with conventional configurations. As a result the amount of deposits formed on the collection cavity surface 116 is reduced, and back-scatter deposition underneath the substrate 180 positioned over the deposition ring is reduced, thereby eliminating the potential for arcing.

In an embodiment, the deposition ring and cover ring are configured to prevent a molecule from reaching the surface where the deposition ring 100 and cover ring 300 come into contact in 3 or less bounces, as defined herein as the “3 Bounce Rule.” The 3 Bounce Rule is premised on the discovery that during PVD type deposition, a molecule is more of a particle after the third bounce and tends to stick on the surface it contacts next. This is significant in at least two respects. Firstly, because the molecules in a PVD type apparatus are more particle-like after the third bounce, they are less likely to form continuous films and instead form discontinuous particle deposits. Secondly, since the molecules possess a lower energy, they tend to stick after the third bounce and cannot tunnel further through the gap between the deposition ring and cover ring. As a result, deposition rings and cover rings complying with the 3 Bounce Rule are able to prevent arcing between the deposition ring and cover ring because a continuously deposited film is not deposited and the potential for an arc path is eliminated and/or minimized.

A configuration complying with the 3 Bounce Rule is provided in FIG. 5A. Deposition ring 100 and cover ring 300 are in spaced apart relation characterized as a Chevron design path 170 for backscatter deposition material to follow. In an embodiment, the spaced apart relation can be characterized as a uniform gap distance. The gap distance and pathlength of the Chevron design path 170 should be sufficient to accumulate stray deposits without providing a direct ground path. In an embodiment, where deposition ring 100 and cover ring 300 are designed for a 200 mm wafer, the Chevron design path 170 has a uniform gap distance between approximately 0.030 inches and 0.090 inches, and a pathlength of approximately 0.237 inches. In embodiments utilizing deposition and cover rings designed for larger substrates the pathlength may be longer. The Chevron design path 170 prevents deposition material from reaching the area where the deposition ring 100 and cover ring 300 come into contact, thus eliminating any arc ground path.

FIG. 5B is an illustration of an alternative embodiment complying with the 3 Bounce Rule. Similar to the configuration in FIG. 5A, the deposition ring 100 in FIG. 5B has a concave collection cavity surface 116 and a protruding surface 118, which is in spaced apart relation with a depressed surface 164 of cover ring 300. A Chevron design path 170 similarly complies with the 3 Bounce Rule. Also, like the configuration in FIG. 5A, the configuration in FIG. 5B allows for more deposits to form on the lip 160 of cover ring 300 than available in conventional configurations.

The isolation notch 120 may also assist with the 3 Bounce rule. As shown in FIG. 5A, in an embodiment, roof 166 is designed to extend over isolation notch 120, and extend beyond both sidewalls 126. Roof 166 is abutted by wall 168, which is designed to be located outside of isolation notch 120. As a result, particles deposit into the isolation notch 120 and are further prevented from reaching the point where the deposition ring 100 and cover ring 300 contact each other. In an alternative embodiment shown in FIG. 5B, wall 168 is designed to hang over isolation notch 120 to prevent particle deposits from reaching the point where the deposition ring 100 and cover ring 300 contact each other.

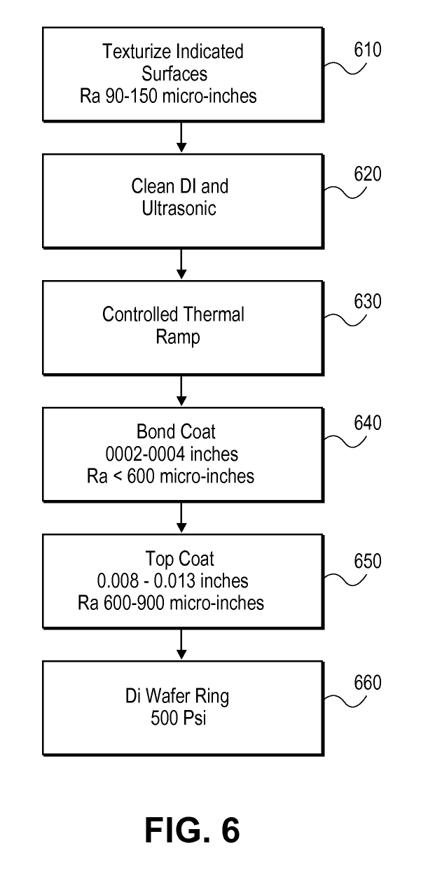

FIG. 6 is an illustration of a method that may be used for forming coatings 140, 170 on indicated surfaces of deposition ring 100, cover ring 300, respectively. At block 610 the indicated surfaces are texturized to have an average surface roughness Ra of approximately 90-150 micro-inches. In an embodiment, surface roughening can be accomplished by bead blasting.

At block 620 the deposition ring or cover ring is cleaned in an ultrasonic bath of DI water. Ultrasonic energy may be applied to remove residual particles from the indicated surfaces. At block 630 the deposition ring or cover ring is exposed to a controlled thermal ramp in order to coalesce any loose surface particles or jagged edges on the indicated surfaces. In an embodiment, the controlled thermal ramp may be from room temperature up to approximately 1600° C., over a period of 24 hours, followed by a hold time of 2 to 4 hours. A suitable ramp down can be approximately 100° C./hr.

At block 640 a first bond coat may be applied to the indicated roughened surfaces. In an embodiment, the bond coat may be applied by twin wire arc spray (TWAS) to a thickness of 0.002-0.004 inches, with an average surface roughness Ra of less than 600 micro-inches. The coating roughness can be controlled by manipulating TWAS parameters such as propellant gas flow rate or nozzle diameter. A top coat is then applied to the bond coat at block 650. In an embodiment, the top coat is applied by TWAS to a thickness of 0.008-0.013 inches, with an average surface roughness Ra of approximately 600-900 micro-inches. Together the bond coat and top coat make up the composite coating 140, 170 on indicated surfaces of deposition ring 100, cover ring 300, respectively. At block 660, the composite coating 140, 170 is then cleaned with a high pressure DI water rinse at approximately 500 psi to 1,000 psi.

The deposition ring 100 and cover ring 300 may also be cleaned and reconditioned for use multiple times after, for example, reaching their designed processing lifetime. Removal of deposition species deposits may be accomplished through the use of selective etch chemistries that will attack the deposition species deposits but not the underlying deposition ring or cover ring. Alternatively, when coating material 140/170 such as a TWAS aluminum coating is present, the coating 140/170 can be removed selectively from the deposition ring and cover ring thereby also removing the deposition species deposits. For example, where the cover ring 300 is formed of titanium, chemistries that attack tantalum metal deposits tend to also attack titanium. Therefore, an etch chemistry is selected that selectively dissolves aluminum coating 170 from beneath the tantalum metal deposits, but not the titanium cover ring 300. Once the deposition ring 100 and cover ring 300 are free of deposits, they are thoroughly cleaned and dried, and then can be processed as if they were new parts through the texturing process and then packaged.

In the foregoing specification, various embodiments of the invention have been described. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A deposition ring comprising:
an inner wall;
a flat inner edge surface proximate the inner wall; and
an inside lip immediately adjacent the flat inner edge surface and forming an obtuse angle with the flat inner edge surface.

2. The deposition ring of claim 1, wherein the inside lip is a portion of a collection cavity surface extending from the flat inner edge surface.

3. The deposition ring of claim 2, further comprising:
an outer wall; and
a flat seat surface proximate the outer wall;
wherein the flat inner edge surface is configured to be positioned parallel to a substrate, and the flat seat surface is configured to support a cover ring.

4. The deposition ring of claim 3, further comprising:
a protruding surface adjacent the collection cavity surface;
wherein the collection cavity surface is below the flat inner edge surface, and the protruding surface extends above the collection cavity surface; and
wherein the collection cavity surface spans a greater horizontal distance than the protruding surface.

5. The deposition ring of claim 4, wherein the protruding surface is rounded.

6. The deposition ring of claim 4, wherein the protruding surface is v-shaped.

7. The deposition ring of claim 3, further comprising:
a depressed surface adjacent the collection cavity surface;
wherein the collection cavity surface is convex and below the flat inner edge surface, and the depressed surface extends below the collection cavity surface; and
wherein the collection cavity surface spans a greater horizontal distance than the protruding surface.

8. The deposition ring of claim 3, further comprising a bond coat on the collection cavity surface.

9. The deposition ring of claim 8, wherein the bond coat has a surface roughness of approximately 600-900 microinches Ra.

10. The deposition ring of claim 9, wherein the collection cavity surface below the bond coat has a surface roughness of approximately 90-150 microinches Ra.

11. A structure comprising:
a deposition ring including a land, and a protruding surface adjacent a collection cavity surface; and
a cover ring seated on the land, and including a depressed surface and an inward extending lip;
wherein the protruding surface is positioned in spaced apart relation with the depressed surface.

12. The structure of claim 11, wherein the protruding surface is curved and described by a first radius, and the depressed surface is curved and described by a second radius larger than the first radius.

13. The structure of claim 12, wherein the deposition ring further comprises a flat inner edge surface positioned parallel to a substrate, wherein the inward extending lip is positioned approximately 23 degrees to normal of an outermost edge of the substrate.

14. The structure of claim 12, further comprising a bond coat on the collection cavity surface.

15. The structure of claim 14, wherein the bond coat has a surface roughness of approximately 600-900 microinches Ra.

16. The structure of claim 15, wherein the collection cavity surface underneath the bond coat has a surface roughness of approximately 90-150 microinches Ra.

17. The structure of claim 12, further comprising a second bond coat on the cover ring.

18. A structure comprising:
a deposition ring including a seat surface;
a cover ring seated on the deposition ring seat surface; and
a means for configuring the deposition ring relative to the cover ring so that a molecule cannot reach the area where the cover ring is seated on the deposition ring seat in three or less bounces.

19. The structure of claim 18, wherein the means for configuring the deposition ring relative to the cover ring so that a molecule cannot reach the area where the cover ring is seated on the deposition ring seat in three or less bounces is:
a curved protruding surface of the deposition ring described by a first radius, and a curved depressed surface of the cover ring described by a second radius larger than the first radius, wherein the protruding surface is positioned in spaced apart relation with the depressed surface.

20. The structure of claim 18, wherein the deposition ring further comprises a flat inner edge surface and an inside lip immediately adjacent the flat inner edge surface, wherein the inside diameter lip forms an obtuse angle with the flat inner edge surface.
